(19) United States
(12) Patent Application Publication
(10) Pub. No.: US 2025/0374602 A1
(43) Pub. Date: Dec. 4, 2025

(54) TENSILE STRESSED NFET NANOSHEETS

(71) Applicant: International Business Machines Corporation, Armonk, NY (US)

(72) Inventors: Takashi Ando, Eastchester, NY (US); Ruilong Xie, Niskayuna, NY (US); Guy M. Cohen, Ossining, NY (US); Nanbo Gong, White Plains, NY (US)

(21) Appl. No.: 18/731,201

(22) Filed: May 31, 2024

(51) Int. Cl. H01L 29/423; H01L 21/8238; H01L 27/092; H01L 29/06; H01L 29/08; H01L 29/66; H01L 29/775; H01L 29/78; H01L 29/786

(52) U.S. Cl. CPC H10D 30/6735; H10D 30/014; H10D 30/43; H10D 30/6757; H10D 30/797; H10D 62/121; H10D 62/151; H10D 64/017; H10D 84/0167; H10D 84/017; H10D 84/038; H10D 84/85

(57) ABSTRACT

Techniques for imparting tensile stress in NFET devices are provided. In one aspect, an exemplary FET device includes: a channel layer disposed on a substrate, where the channel layer has both horizontal and vertical portions, and where the vertical portions of the channel layer connect adjacent ones of the horizontal portions; a gate surrounding the channel layer (i.e., in a gate-all-around configuration); and source/drain regions on opposite ends of the channel layer. Portions of the gate can be present between the horizontal portions of the channel layer. A method of fabricating the present FET devices is also provided.

### BACKGROUND

The present invention relates generally to the electrical, electronic and computer arts and, more particularly, to integrated circuits such as complementary metal oxide semiconductor (CMOS) integrated circuits.

A stacked nanosheet transistor is a promising device architecture for the 5 nanometer (nm) technology node and beyond. In a stacked nanosheet transistor, nanosheets are stacked horizontally, one on top of another. Advantageously, the nanosheets can be released from the stack and suspended to enable a gate-all-around structure.

However, with conventional stacked nanosheet transistor process flows, channel strain is relaxed after releasing and suspending the nanosheets. It is difficult to then apply external strain afterwards. Thus, enhancing the performance of stacked nanosheet transistors via channel strain remains a significant challenge and a roadblock for continued CMOS scaling.

### BRIEF SUMMARY

Principles of the invention provide techniques for effectively providing tensile stressed n-channel field effect transistor (NFET) devices. In one aspect, an exemplary field effect transistor (FET) device includes: a channel layer disposed on a substrate, where the channel layer has both horizontal and vertical portions, and where the vertical portions of the channel layer connect adjacent ones of the horizontal portions; a gate surrounding the channel layer; and source/drain regions on opposite ends of the channel layer.

In another aspect, another exemplary FET device includes: a channel layer of tensile strained silicon (Si) disposed on a substrate, where the channel layer has both horizontal and vertical portions, and where the vertical portions of the channel layer connect adjacent ones of the horizontal portions; a gate surrounding the channel layer in a gate-all-around configuration, where portions of the gate are present between the horizontal portions of the channel layer; and source/drain regions on opposite ends of the channel layer.

In yet another aspect, an exemplary method of fabricating a FET device includes: forming a nanosheet stack on a substrate, the nanosheet stack having a first sacrificial nanosheet disposed on the substrate, and alternating second and third sacrificial nanosheets disposed on the first sacrificial nanosheet; selectively removing the second sacrificial nanosheets from the nanosheet stack; depositing a channel layer on the third sacrificial nanosheets, where the channel layer has both horizontal and vertical portions, and where the vertical portions of the channel layer connect adjacent ones of the horizontal portions; depositing a sacrificial filler layer over the channel layer; forming source/drain regions on opposite ends of the channel layer; selectively removing the third sacrificial nanosheets and the sacrificial filler layer; and forming a gate that surrounds the channel layer in a gate-all-around configuration.

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
An easy and effective way to impart tensile strain in stacked nanosheet n-channel field effect transistor (FET) devices in order to improve electron mobility therein;
The present techniques can be implemented with a gate-all-around configuration in order to reduce leakage and increase drive current;
Provides a unique channel layer design having fully or partially connected horizontal and vertical portions which significantly increases the device effective width at a given footprint area.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-27 are views of a field effect transistor device at different steps in a manufacturing process according to one or more embodiments of the present invention, where FIG. 1 is a top-down view and the remaining figures are cross-sectional views; and

FIGS. 28-45 are cross-sectional views, which follow from FIG. 6 and FIG. 7, of a field effect transistor device at different steps in an alternative manufacturing process according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As highlighted above, a notable challenge associated with implementing a stacked nanosheet transistor architecture is being able to effectively apply strain on the nanosheet channels, since any such strain is relaxed as soon as the nanosheets are released from the stack. Strain can enhance carrier transport in the nanosheet channels. For instance, a biaxial tensile strain has been shown to improve electron mobility in n-channel field effect transistors (NFETs), while a uniaxial compressive strain has been shown to improve hole mobility in p-channel field effect transistors (PFETs).

Advantageously, provided herein are stacked nanosheet NFET devices with tensile-stressed nanosheet channels and techniques for fabrication thereof, where epitaxially grown silicon (Si) channel layers are formed on sacrificial, free-standing silicon germanium (SiGe) templates. The resulting Si channel layers are tensile strained, and that strain is effectively maintained throughout the fabrication process. The term “sacrificial” as used herein refers to a material or structure that is used in one part of the process, and then later removed, in whole or in part, during fabrication of the device.

As will be described in detail below, the present tensile-strained Si channel layers have a unique configuration, containing both horizontal and vertical portions, with the vertical portions connecting adjacent horizontal portions. By way of a non-limiting example, “a channel layer disposed on a substrate, wherein the channel layer comprises both horizontal and vertical portions” could have two or more horizontal portions AND one or more vertical portions. For instance, in one exemplary embodiment, the vertical portions connect every adjacent pair of the horizontal portions from alternating sides, which results in a serpentine configuration of the tensile-strained Si channel layers. In another exemplary embodiment, the vertical portions partially connect adjacent pairs of the horizontal portions, which results in sideways-facing U-shaped segments of the tensile-strained Si channel layers.

In either case, the above-mentioned structures of the Si channel layers advantageously enable the introduction of tensile strain in the present stacked nanosheet NFET devices to boost their performance. Notably, this tensile strain is effectively maintained throughout the fabrication process. Another notable benefit of the present techniques is that the effective device width of the resulting stacked nanosheet NFET devices is much larger as compared to conventional stacked nanosheet structures, which advantageously provides a higher drive current. Namely, with conventional stacked nanosheet structures, the nanosheet channels are planar sheets that extend horizontally from one end of the device to the other. By comparison, as highlighted above, the present tensile-strained Si channel layers have both horizontal and vertical components thereby providing a significantly greater device width.

Further, the configurations of the present tensile-strained Si channel layers enable the implementation of a gate-all-around configuration whereby the gate of the device (for instance a high-K metal gate as described below) fully wraps around at least a portion of each of the tensile-strained Si channel layers. Use of a gate-all-around configuration advantageously suppresses short channel effects and increases drive current.

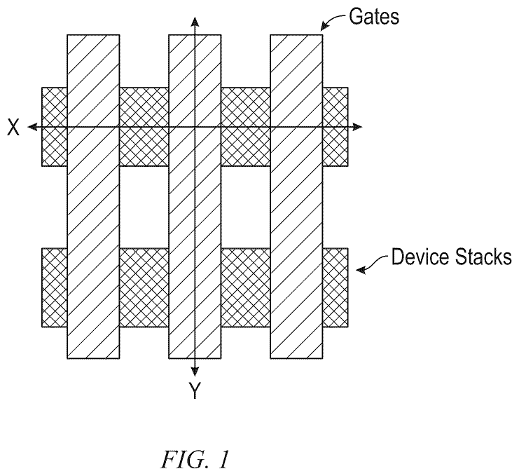

Given the above overview, an exemplary process for fabricating a field effect transistor (FET) device in accordance with the present techniques is now described by way of reference to FIGS. 1-27. As a point of reference for the cross-sectional cuts that will be presented in the figures that follow, the overall layout of the present semiconductor device is first depicted in FIG. 1 by way of a top-down view. Namely, as shown in FIG. 1, in one or more exemplary embodiments the present semiconductor device will include multiple device stacks and multiple gates, oriented orthogonal to one another, and extending arbitrarily along an X-direction and a Y-direction, respectively.

In FIG. 1, the gates shown are representative of sacrificial gates that will be formed over the device stacks as part of a gate-last process. As would be apparent to one of ordinary skill in the art, with a gate-last process such sacrificial gates are formed early on in the process and serve as a placeholder for positioning other device components such as source/drain regions. Accordingly, following placement of the source/drain regions, the sacrificial gates can then be removed and replaced with the final or “replacement” gates of the device. As such, the orientation of the replacement gates will be the same as that of the sacrificial gates shown in FIG. 1. When these replacement gates are metal, they are also referred to herein as “replacement metal gates.” Advantageously, use of a gate-last process avoids exposing the replacement metal gate materials like high-k dielectrics to potentially damaging conditions such as the high temperatures experienced during source/drain region formation.

As highlighted above, the process flow will be described by way of reference to different cross-sectional cuts through the FET device. As shown in FIG. 1, the X cross-sectional views provided herein represent cuts through the FET device in the X-direction, i.e., along one of the device stacks. The Y cross-sectional views represent cuts through the FET device in the Y-direction, i.e., across the device stacks along one of the gates.

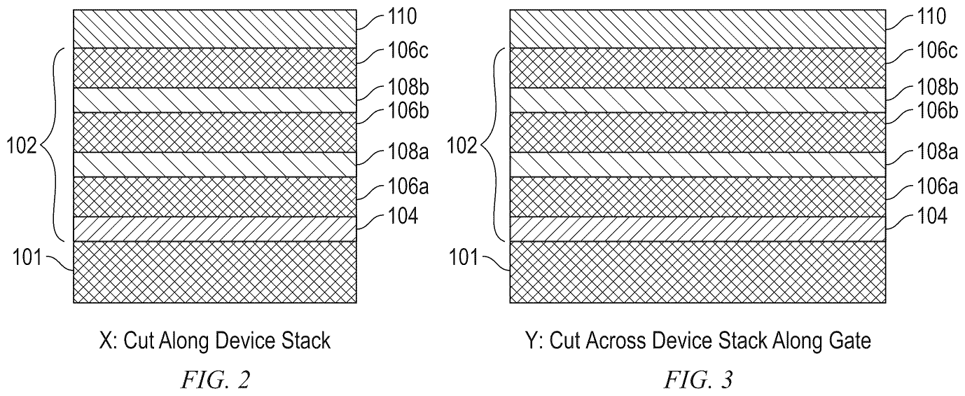

As shown in FIG. 2 (an X cross-sectional view) and FIG. 3 (a Y cross-sectional view), the process begins with the formation of a nanosheet stack 102 on a substrate 101. According to an exemplary embodiment, substrate 101 is a bulk semiconductor wafer, such as a bulk silicon (Si), bulk germanium (Ge), bulk silicon germanium (SiGe) and/or bulk III-V semiconductor wafer. Alternatively, substrate 101 can be a semiconductor-on-insulator (SOI) wafer. A SOI wafer includes an SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, substrate 101 may already have pre-built structures (not shown) such as transistors, diodes, capacitors, resistors, interconnects, wiring, etc.

According to an exemplary embodiment, nanosheet stack 102 includes a first sacrificial nanosheet 104 blanket deposited on substrate 101, and alternating second and third sacrificial nanosheets 106a,b,c, etc. and 108a,b, etc. blanket deposited horizontally one on top of another on first sacrificial nanosheet 104. It is notable that the number of second and third sacrificial nanosheets 106c, 106b, 106c (hereinafter 106a, b, c, etc.) and 108a, 108b (hereinafter, 108a, b, etc.) shown in the figures is provided merely as an example to illustrate the present techniques. For instance, embodiments are contemplated herein where more or fewer second sacrificial nanosheets 106a,b,c, etc. and/or more or fewer third sacrificial nanosheets 108a,b, etc. are present than shown. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa.

By way of example only, the first, second and third sacrificial nanosheets 104, 106a,b,c, etc. and 108a,b, etc. can be blanket deposited onto the substrate 101 using an epitaxial growth process. Unless otherwise specified, the term “epitaxial growth” indicates a crystalline film. According to an exemplary embodiment, each of the first, second and third sacrificial nanosheets 104, 106a,b,c, etc. and 108a,b, etc. has a thickness of from about 15 nanometers (nm) to about 25 nm.

As will be described in detail below, the first sacrificial nanosheet 104 will be removed later on in the process to permit the formation of a dielectric that serves to prevent source-to-drain leakage via the substrate 101. After that, the second sacrificial nanosheets 106a,b,c, etc. will be removed to suspend the third sacrificial nanosheets 108a,b, etc. and to permit the formation of the present tensile-strained Si channel layers on the (suspended) third sacrificial nanosheets 108a,b, etc. The third sacrificial nanosheets 108a,b, etc. will then be subsequently removed to enable the formation of the replacement gates that surround at least a portion of the tensile-strained Si channel layers in a gate-all-around configuration.

Therefore, the materials chosen for the first, second and third sacrificial nanosheets 104, 106a,b,c, etc., and 108a,b, etc. are such that they will enable selective removal of the first, second and third sacrificial nanosheets 104, 106a,b,c, etc., and 108a,b, etc. at different times in the process. For instance, in one exemplary embodiment the second sacrificial nanosheets 106a,b,c, etc. are each formed from Si, while the third sacrificial nanosheets 108a,b, etc. are each formed from SiGe. Etchants such as wet hot SC1, vapor phase hydrogen chloride (HCl), vapor phase chlorine trifluoride (CIF₃) and other reactive clean processes (RCP) are selective for etching of SiGe versus Si. Etchants such as ammonium hydroxide (NH₄OH) or tetramethyl ammonium hydroxide (TMAH) are selective for etching of Si versus SiGe.

Further, high germanium (Ge) content SiGe can be removed selective to low Ge content SiGe using an etchant such as dry HCl. Thus, according to an exemplary embodiment, first sacrificial nanosheet 104 is formed from SiGe having a high Ge content. For instance, in one exemplary embodiment, high Ge content SiGe is SiGe having from about 45% Ge to about 70% Ge. For instance, in one non-limiting example, first sacrificial nanosheet 104 is formed from SiGe55 (which is SiGe having a Ge content of about 55%). In that case, third sacrificial nanosheets 108a,b, etc. are preferably formed from a low Ge content SiGe. For instance, in one exemplary embodiment, low Ge content SiGe is SiGe having from about 15% Ge to about 35% Ge. For example, in one non-limiting embodiment, third sacrificial nanosheets 108a,b, etc. are formed from SiGe25 (which is SiGe having a Ge content of about 25%).

A hardmask 110 is then deposited onto the nanosheet stack 102. Suitable materials for hardmask 110 include, but are not limited to, silicon nitride (SiN), silicon dioxide (SiO₂), titanium nitride (TiN) and/or silicon oxynitride (SiON). The hardmask 110 will be used to define an active area of the FET device in the nanosheet stack 102.

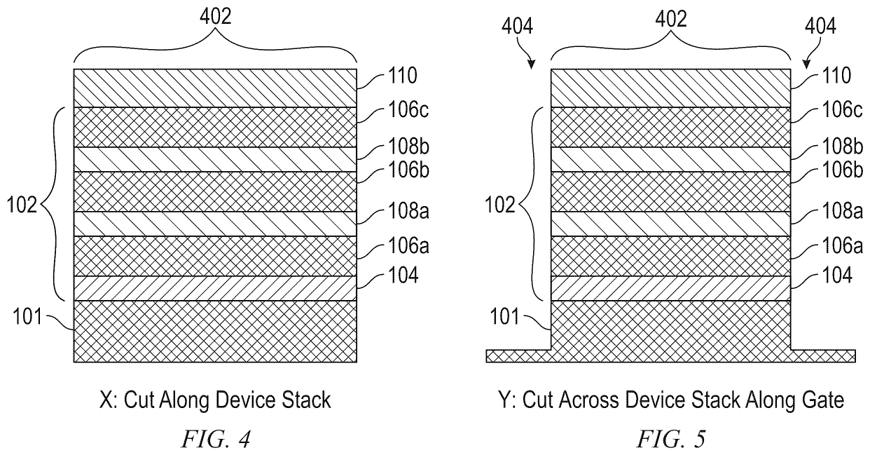

Namely, as shown in in FIG. 4 (an X cross-sectional view) and FIG. 5 (a Y cross-sectional view), the hardmask 110 is patterned with the footprint and location of an active area 402 of the FET device, and that pattern is then transferred to the nanosheet stack 102. Standard lithography and etching techniques can be employed to pattern the hardmask 110. With standard lithography and etching techniques, a lithographic stack (not shown), e.g., photoresist/anti-reflective coating/organic planarizing layer, is used to pattern the hardmask 110. Alternatively, the hardmask 110 can be formed by other suitable techniques, including but not limited to, sidewall image transfer (SIT), self-aligned double patterning (SADP), self-aligned quadruple patterning (SAQP), and other self-aligned multiple patterning (SAMP).

An etch is then performed to transfer the pattern from the hardmask 110 to the underlying nanosheet stack 102. By way of example only, a directional (i.e., anisotropic) etching process such as reactive ion etching can be employed to pattern the nanosheet stack 102 in the active area 402 of the FET device. As shown particularly in FIG. 5, the etch of nanosheet stack 102 can also extend partway into the substrate 101. The depth of this ‘overetch’ into the substrate 101 depends on the level of control over the endpoint of the etching process. As a result, trenches 404 are formed along opposite sides of the nanosheet stack 102 and substrate 101.

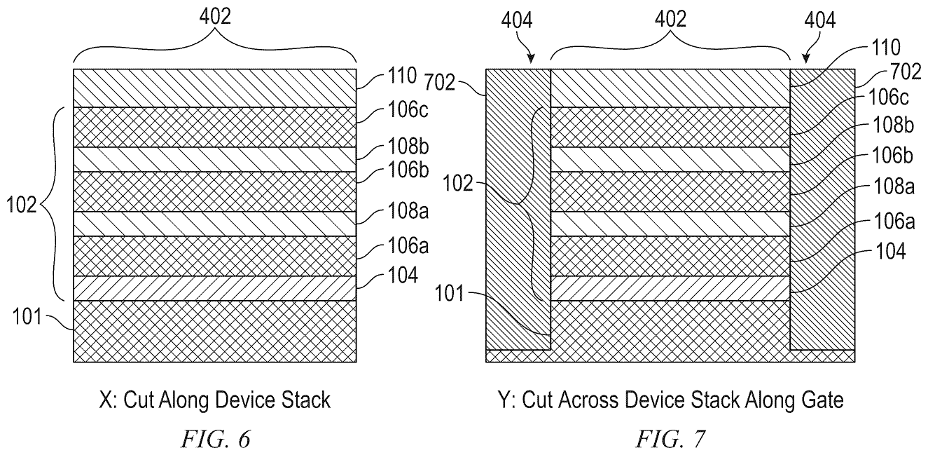

As shown in in FIG. 6 (an X cross-sectional view) and FIG. 7 (a Y cross-sectional view), an interlayer dielectric 702 is then deposited into and filling the trenches 404, and then planarized. Suitable interlayer dielectrics 702 include, but are not limited to, oxide low-K materials such as silicon oxide (SiOx) and/or oxide ultralow-K interlayer dielectric (ULK-ILD) materials, e.g., having a dielectric constant κ of less than 2.7. Suitable ultralow-κ dielectric materials include, but are not limited to, porous organosilicate glass (pSiCOH). A process such as chemical vapor deposition (CVD), atomic layer deposition (ALD) or physical vapor deposition (PVD) can be used to deposit the interlayer dielectric 702, after which the interlayer dielectric 702 can be planarized using a process such as chemical mechanical polishing (CMP).

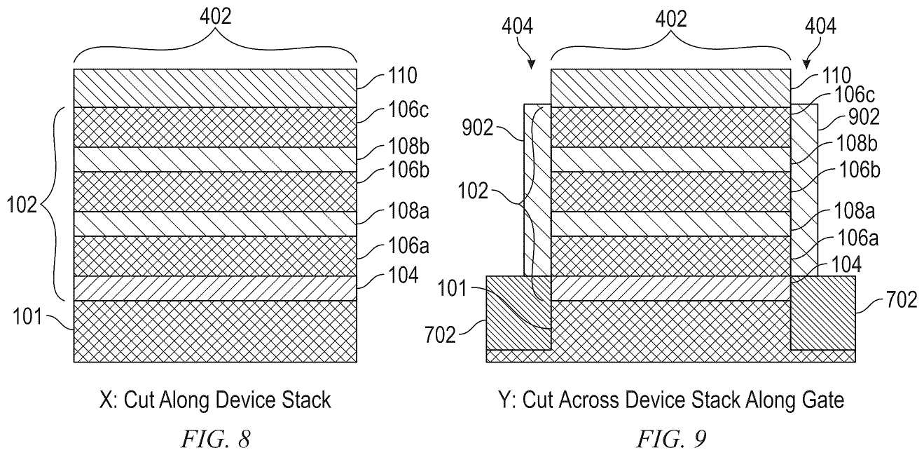

As shown in in FIG. 8 (an X cross-sectional view) and FIG. 9 (a Y cross-sectional view), the interlayer dielectric 702 is then partially recessed to reopen the trenches 404, and epitaxial sidewalls 902 are grown along opposite sides of a portion of the nanosheet stack 102. The interlayer dielectric 702 can be recessed using a dry or wet etching process.

As shown particularly in FIG. 9, the interlayer dielectric 702 is preferably recessed to the point where i) the second and third sacrificial nanosheets 106a,b,c, etc., and 108a,b, etc. are exposed along the sidewall of the nanosheet stack 102, while ii) the first sacrificial nanosheet 104 remains covered by the interlayer dielectric 702 along the sidewall of the nanosheet stack 102. The epitaxial sidewalls 902 are then grown on opposite sides of the nanosheet stack 102 alongside the exposed second and third sacrificial nanosheets 106a,b,c, etc., and 108a,b, etc. According to an exemplary embodiment, like the third sacrificial nanosheets 108a,b, etc., the epitaxial sidewalls 902 are also formed from a low Ge content SiGe (i.e., SiGe having from about 15% Ge to about 35% Ge). For example, in one non-limiting embodiment, epitaxial sidewalls 902 are formed from SiGe25. In one embodiment, the epitaxial sidewalls 902 have a thickness of from about 15 nm to about 25 nm.

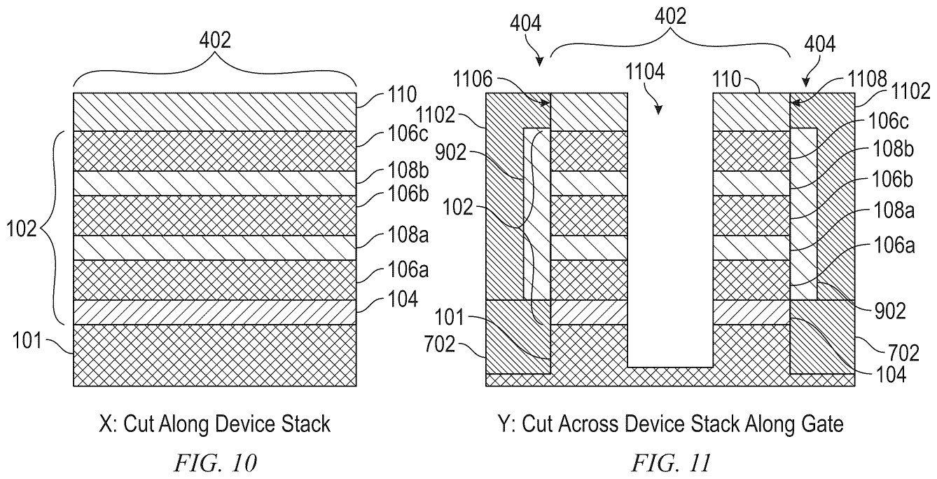

As shown in FIG. 10 (an X cross-sectional view) and FIG. 11 (a Y cross-sectional view), an interlayer dielectric 1102 is deposited into and filling the trenches 404 over the (recessed) interlayer dielectric 702 and planarized, and the hardmask 110 is used to pattern a trench 1104 in the nanosheet stack 102 forming at least a first device stack 1106 and a second device stack 1108. For clarity, the terms ‘first’ and ‘second’ may also be used herein when referring to interlayer dielectric 702 and interlayer dielectric 1102, respectively.

As provided above, suitable interlayer dielectric 1102 materials include, but are not limited to, oxide low-κ materials such as SiOx and/or oxide ULK-ILD materials such as pSiCOH. A process such as CVD, ALD or PVD can be used to deposit the interlayer dielectric 1102, after which the interlayer dielectric 1102 can be planarized using a process such as chemical mechanical polishing.

Standard lithography and etching techniques (see above) can be employed to pattern the hardmask 110 with the footprint and location of the trench 1104. A directional (i.e., anisotropic) etching process such as reactive ion etching (RIE) can then be employed to transfer the pattern to the nanosheet stack 102 forming the trench 1104. As shown particularly in FIG. 11, the etch of trench 1104 can extend partway into the substrate 101. The depth of this ‘overetch’ into the substrate 101 depends on the level of control over the endpoint of the etching process. The patterning of trench 1104 in nanosheet stack 102 results in the formation of the at least two distinct first/second device stacks 1106 and 1108 (which are representative of the exemplary device stacks shown in the top-down view of FIG. 1).

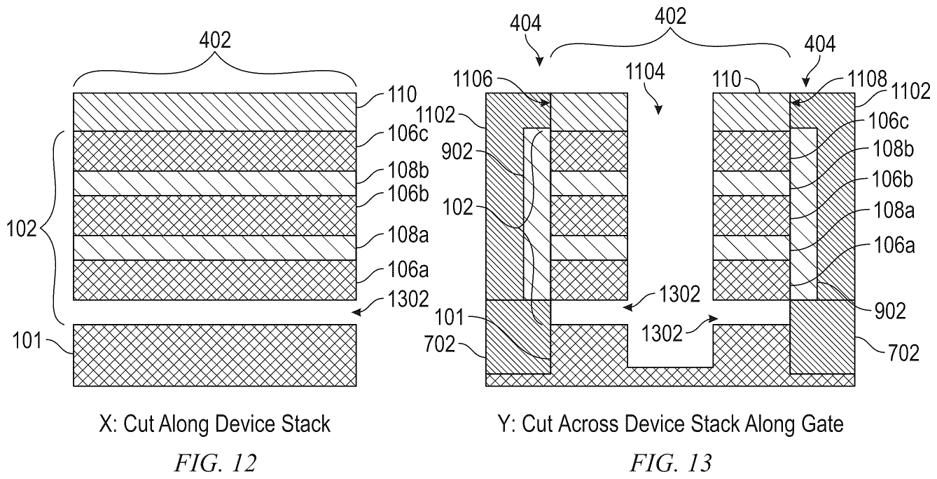

As shown in in FIG. 12 (an X cross-sectional view) and FIG. 13 (a Y cross-sectional view), the first sacrificial nanosheet 104 is selectively removed from the nanosheet stack 102 via the trench 1104. The first sacrificial nanosheet 104 will be replaced with a dielectric (see below) that serves to prevent source-to-drain leakage via the substrate 101.

As provided above, the first sacrificial nanosheet 104 can be formed from SiGe having a high Ge content (i.e., SiGe having from about 45% Ge to about 70% Ge) such as SiGe55, while the third sacrificial nanosheets 108a,b, etc. and the epitaxial sidewalls 902 can be formed from a low Ge content SiGe (i.e., SiGe having from about 15% Ge to about 35% Ge) such as SiGe25. In that case, an etchant such as dry HCl can be employed to remove the first sacrificial nanosheet 104 (having a high Ge content) selective to the third sacrificial nanosheets 108a,b, etc. and the epitaxial sidewalls 902 (having a low Ge content), and selective to the second sacrificial nanosheets 106a,b,c, etc. (Si). Selective removal of the first sacrificial nanosheet 104 forms a cavity 1302 in the nanosheet stack 102.

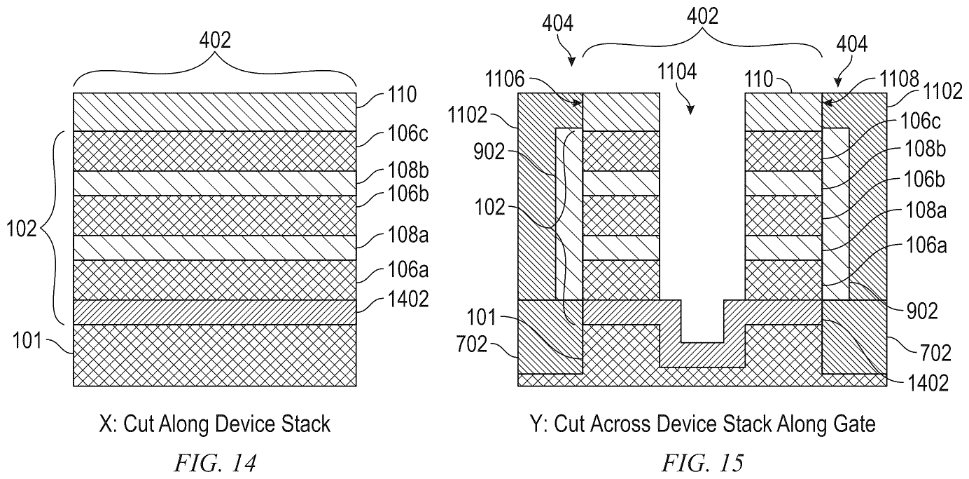

As shown in in FIG. 14 (an X cross-sectional view) and FIG. 15 (a Y cross-sectional view), a dielectric material is deposited into the trench 1104 and cavity 1302, and then chamfered to form a dielectric 1402 that separates/isolates the remaining nanosheet stack 102 (i.e., the second and third sacrificial nanosheets 106a,b,c, etc., and 108a,b, etc.) from the substrate 101. As highlighted above, this dielectric 1402 will advantageously serve to prevent source-to-drain leakage via the substrate 101.

Suitable materials for dielectric 1402 include, but are not limited to nitride dielectric materials such as silicon nitride (SiN), silicon oxynitride (SiOₓN_{y}) and/or silicon oxycarbonitride (SiOCN). A process such as CVD or ALD can be used to deposit the dielectric 1402, after which the dielectric 1402 can be recessed such that dielectric 1402 remains only at the bottom of the trench 1104 and fully filling the cavity 1302, as shown in FIGS. 14 and 15. A sacrificial material, such as an organic planarization layer (OPL) (not shown), can be used to enable removal of the dielectric 1402 from the sidewall of the trench 1104 while protecting the dielectric 1402 at the bottom of the trench 1104. The OPL layer is then removed after the recessing process.

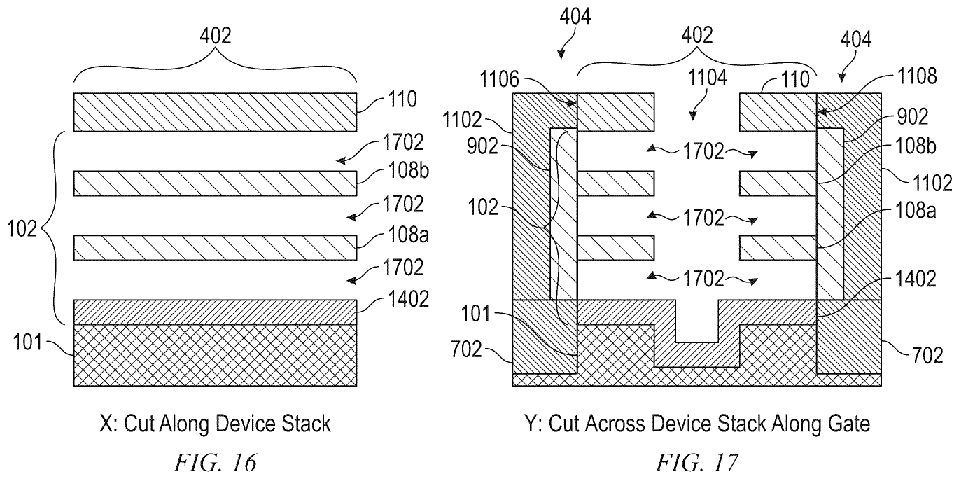

As shown in in FIG. 16 (an X cross-sectional view) and FIG. 17 (a Y cross-sectional view), the second sacrificial nanosheets 106a,b,c, etc. are selectively removed from the nanosheet stack 102 via the trench 1104. As will be described in detail below, removal of the second sacrificial nanosheets 106a,b,c, etc. enables growth of the present tensile-strained Si channel layers over the now exposed surfaces of the third sacrificial nanosheets 108a,b, etc.

As provided above, the second sacrificial nanosheets 106a,b,c, etc. can be formed from Si, while the third sacrificial nanosheets 108a,b, etc. and the epitaxial sidewalls 902 can be formed from SiGe. In that case, an etchant such as ammonium hydroxide (NH₄OH) or tetramethyl ammonium hydroxide (TMAH) can be employed to remove the second sacrificial nanosheets 106a,b,c, etc. selective to the third sacrificial nanosheets 108a,b, etc. and the epitaxial sidewalls 902. Selective removal of the second sacrificial nanosheets 106a,b,c, etc. forms openings 1702 in the nanosheet stack 102 between the third sacrificial nanosheets 108a,b, etc./epitaxial sidewalls 902.

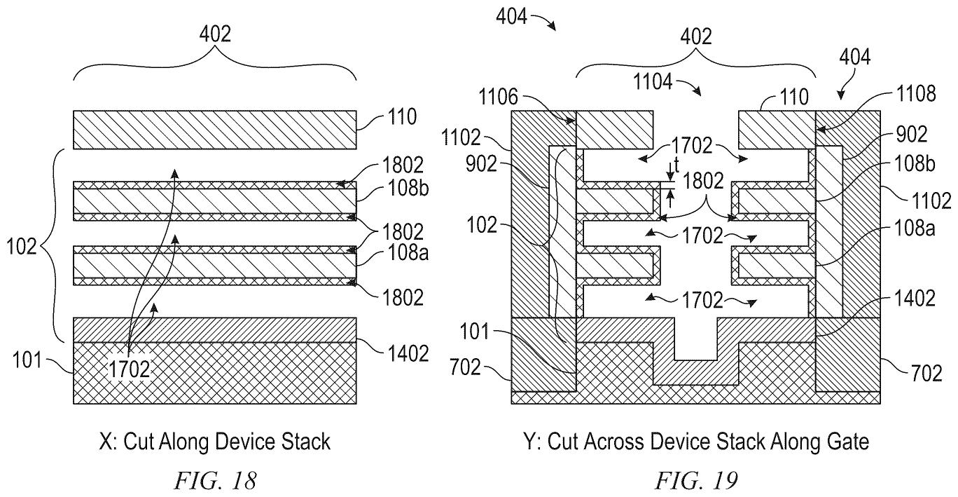

As shown in in FIG. 18 (an X cross-sectional view) and FIG. 19 (a Y cross-sectional view), channel layers 1802 are then deposited (e.g., epitaxially grown) in the openings 1702 on the exposed surfaces of the third sacrificial nanosheets 108a,b, etc. and the epitaxial sidewalls 902. The channel layers 1802 are preferably formed from a material having a larger elastic constant than the material on which the channel layers 1802 are epitaxially grown, namely the third sacrificial nanosheets 108a,b, etc. and the epitaxial sidewalls 902. Doing so can serve to impart tensile strain on the channel layers 1802 which, as highlighted above, advantageously improves electron mobility in NFETs.

For instance, according to an exemplary embodiment, the third sacrificial nanosheets 108a,b, etc. and the epitaxial sidewalls 902 are formed from SiGe, and the channel layers 1802 are formed from Si. As known to those of skill in the art, SiGe has a larger lattice constant than Si. Thus, when Si is grown epitaxially in this manner, the exposed SiGe surfaces of the third sacrificial nanosheets 108a,b, etc. and the epitaxial sidewalls 902 act as a template for how the Si atoms are arranged. Since, SiGe has a larger lattice constant from that of Si, in order for the Si to match that template it has to be strained somehow, meaning the Si has to assume a different lattice parameter than it would have if it was deposited directly on another Si substrate. This causes the Si to stretch resulting in tensile stressed (Si) channel layers 1802.

Further, if both structures (i.e., the SiGe template and the Si being epitaxially grown) are comparable in size, they will share the strain. In that case, as the Si grows on the SiGe, the SiGe will also be pulled because of the new layer of Si. The amount of strain shared is based on the relative thickness of the layers. However, according to an exemplary embodiment, the channel layers 1802 have a thickness t of from about 4 nm to about 10 nm, which is thinner than the third sacrificial nanosheets 108a,b, etc. and the epitaxial sidewalls 902 on which the channel layers 1802 are grown. For instance, as provided above, the third sacrificial nanosheets 108a,b, etc. and the epitaxial sidewalls 902 each have a thickness of from about 15 nm to about 25 nm. Accordingly, the relatively thinner Si channel layers 1802 will be fully strained, without having much, if any, effect on the SiGe third sacrificial nanosheets 108a,b, etc. and epitaxial sidewalls 902.

Additionally, as will be described in detail below, when at the present thickness t (i.e., of from about 4 nm to about 10 nm), the channel layers 1802 can sustain a channel length (i.e., source to drain distance) of less than or equal to about 100 nm and greater than or equal to about 300 megapascal (MPa) of stress (e.g., from about 300 MPa to about 1 gigapascal (GPa) of stress) without the risk of buckling which needs to be avoided when the channel layers 1802 are released for the gate-all-around process (see below).

Stress and strain are both tensors. Strain can be directly linked to an increase in the electron mobility, and thus is also a useful metric for evaluating the advantages of aspects of FET designs in accordance with aspects of the invention. More specifically, strain is directly linked to the deformation in the lattice structure that leads to a change in the band structure, which in turn impacts electron mobility. Strain (e) can be defined as the change in length (ΔL) per unit of the original length L, i.e.,

e=ΔL/L.

If there is an increase in the length of the material line, the strain is called tensile strain. On the other hand, if there is a reduction or compression in the length of the material line, it is called compressive strain. For channel layers in accordance with one or more embodiments, the strain is in the direction from the source to the drain (along the channel direction). According to an exemplary embodiment, the strain (e) is greater than or equal to about 0.2%, preferably greater than or equal to about 0.5%.

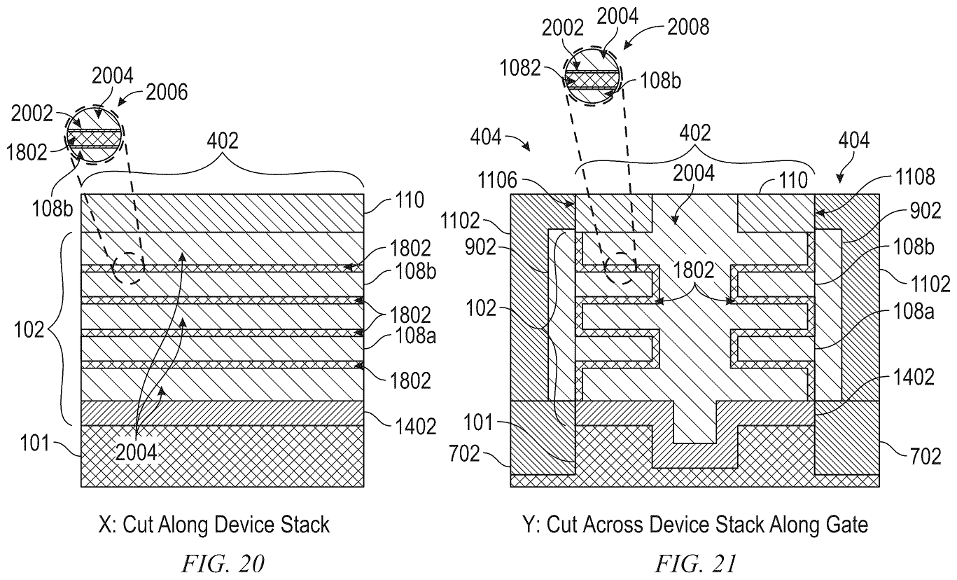

As shown in in FIG. 20 (an X cross-sectional view) and FIG. 21 (a Y cross-sectional view), a sacrificial filler layer 2004 is deposited into, and filling, the trench 1104 and openings 1702 over the channel layers 1802. In the instant exemplary embodiment, the third sacrificial nanosheets 108a,b, etc. and the epitaxial sidewalls 902 are formed from SiGe, and the channel layers 1802 are formed from Si. In that case, the sacrificial filler layer 2004 is formed from SiGe, which can be deposited using a process such as thermal CVD or plasma-enhanced CVD. Doing so will later enable the concurrent removal of the third sacrificial nanosheets 108a,b, etc., the epitaxial sidewalls 902, and the sacrificial filler layer 2004 during replacement gate formation (see below) since they are all formed from the same material, in this case SiGe. According to one exemplary, non-limiting embodiment, sacrificial filler layer 2004 is formed from amorphous SiGe. Use of an amorphous material in this step will help to prevent the sacrificial filler layer 2004 from affecting the tensile strain already imparted on the channel layers 1802 by the third sacrificial nanosheets 108a,b, etc. and the epitaxial sidewalls 902.

As shown in magnified view 2006 (of FIG. 20) and magnified view 2008 (of FIG. 21), an optional oxide layer 2002 (e.g., SiO₂) may first be deposited on the exposed surfaces of the channel layers 1802 prior to deposition of the sacrificial filler layer 2004. By way of example only, the oxide layer 2002 may be formed on the channel layers 1802 using a process such as thermal oxidation, to a thickness of from about 0.5 nm to about 1 nm. Use of the (optional) oxide layer 2002 will help avoid growth of single-crystal SiGe, in favor of the above-described amorphous SiGe. However, it is notable that native oxide on the surfaces of the channel layers 1802 may be sufficient to prevent growth of crystalline SiGe without the need for the intentional formation of SiO₂. As such, oxide layer 2002 is optional.

As provided above, the present exemplary process flow employs a gate-last process whereby sacrificial gates are used as a placeholder for positioning device components such as source/drain regions. Later on, the sacrificial gates are removed and replaced with the final or “replacement” gates of the device.

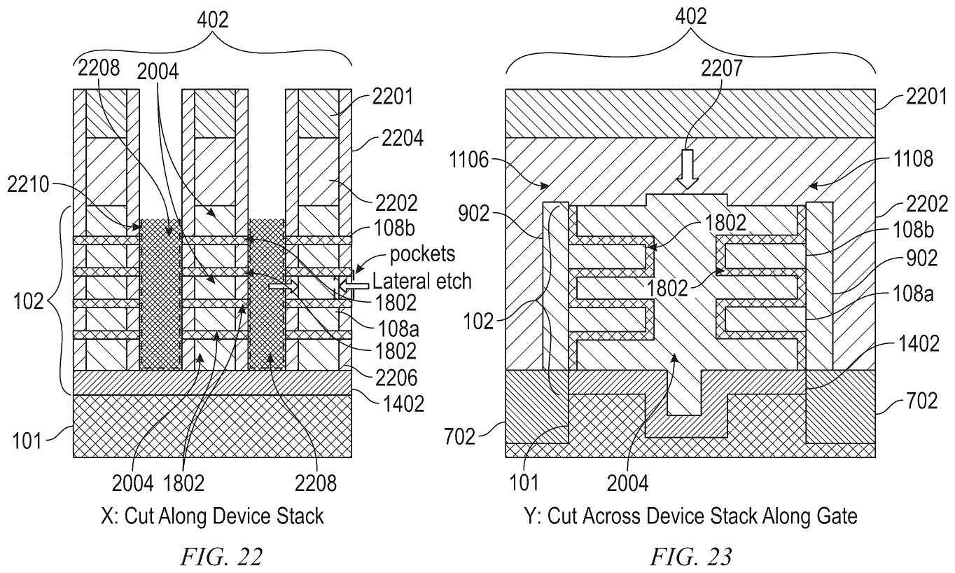

Accordingly, as shown in in FIG. 22 (an X cross-sectional view) and FIG. 23 (a Y cross-sectional view), the sacrificial filler layer 2004 is recessed, the (second) interlayer dielectric 1102 is recessed, the hardmask 110 is removed, sacrificial gates 2202 are formed over the nanosheet stack 102, gate spacers 2204 are formed alongside the sacrificial gates 2202 and the sacrificial filler layer 2004, inner spacers 2206 are formed alongside the third sacrificial nanosheets 108a,b, etc. and sacrificial filler layer 2004, and source/drain regions 2208 are formed on opposite ends of the channel layers 1802. The source/drain regions 2208 are offset from the sacrificial filler layer 2004 and the third sacrificial nanosheets 108a,b, etc. by the gate spacers 2204 and the inner spacers 2206, respectively.

Recess of the sacrificial filler layer 2004 is represented schematically by arrow 2207 in FIG. 23. As provided above, the sacrificial filler layer 2004 can be formed from SiGe, which can be selectively patterned using etchants such as wet hot SC1, vapor phase HCl, vapor phase CIF₃ and other RCPs. The (second) interlayer dielectric 1102 can be recessed using a dry or wet etching process. As shown particularly in FIG. 23, embodiments are contemplated herein where the (second) interlayer dielectric 1102 is fully recessed down to the (first) interlayer dielectric 702. As such, the nanosheet stack 102 above the dielectric 1402 is fully exposed. What remains of the hardmask 110 can then be removed using a nitride- or oxide-selective etch, as the case may be (see above).

To form the sacrificial gates 2202, a sacrificial gate material is first blanket deposited over the nanosheet stack 102. Suitable sacrificial gate materials include, but are not limited to, poly-silicon and/or amorphous silicon. A process such as CVD, ALD or PVD can be used to deposit the sacrificial gate material, after which the sacrificial gate material can be planarized using a process such as chemical mechanical polishing. Standard lithography and etching techniques (see above) are then used to pattern gate hardmasks 2201 on the sacrificial gate material marking the footprint and location of the sacrificial gates 2202. A directional (i.e., anisotropic) etching process such as reactive ion etching can be employed to transfer the pattern from the gate hardmasks 2201 to the sacrificial gate material, forming the sacrificial gates 2202 over the nanosheet stack 102 (which are representative of the exemplary gates shown in the top-down view of FIG. 1).

To form the gate spacers 2204, a dielectric spacer material is first deposited over the nanosheet stack 102, followed by a directional (anisotropic) etching process such as reactive ion etching to pattern the dielectric spacer material into the gate spacers 2204 alongside the sacrificial gates 2202 and the sacrificial filler layer 2004. Suitable dielectric spacer materials include, but are not limited to, SiOx, silicon carbide (SiC), silicon oxycarbide (SiCO), SiN, silicoboron carbonitride (SiBCN) and/or silicon oxycarbonitride (SiOCN), which can be deposited using a process such as CVD, ALD or PVD.

As shown particularly in FIG. 22, the gate hardmasks 2201/sacrificial gates 2202 and gate spacers 2204 are then used as a mask to pattern trenches 2210 in the nanosheet stack 102, the outlines of which are depicted with dashed lines. A directional (anisotropic) etching process such as reactive ion etching can be employed to form the trenches 2210.

To form the inner spacers 2206, a selective lateral etch is performed to first recess the third sacrificial nanosheets 108a,b, etc. and the sacrificial filler layer 2004 exposed along the sidewalls of the trenches 2210. This recess etch forms pockets along the sidewalls of the trenches 2210 that are then filled with a dielectric spacer material to form the inner spacers 2206 within the pockets. The inner spacers 2206 will serve to offset the replacement gates from the source/drain regions (see below). As provided above, the third sacrificial nanosheets 108a,b, etc. and the sacrificial filler layer 2004 can be formed from SiGe. In that case, a SiGe-selective non-directional (isotropic) etching process can be used for the recess etch. Suitable dielectric spacer materials for inner spacers 2206 include, but are not limited to, silicon nitride (SiN), SiOx, SiC and/or SiCO. A process such as CVD, ALD or PVD can be employed to deposit the dielectric spacer material into the pockets, after which excess spacer material can be removed from the trenches 2210 using an isotropic etching process such as reactive ion etching.

Source/drain regions 2208 are then formed on opposite ends of the channel layers 1802. As provided above, a goal of the present techniques is to fabricate tensile stressed NFET devices. Thus, according to an exemplary embodiment, the source/drain regions 2208 are formed from an n-type in-situ doped (i.e., during growth) or ex-situ doped (e.g., via ion implantation) epitaxial material such as epitaxial Si, epitaxial SiGe, etc. Suitable n-type dopants include, but are not limited to, phosphorous (P) and/or arsenic (As).

Notably, as shown, for example, in FIG. 22, the source/drain regions 2208 now anchor the ends of the channel layers 1802. In this manner, the tensile strain present in the channel layers 1802 can be maintained (i.e., anchored) even after the third sacrificial nanosheets 108a,b, etc., the epitaxial sidewalls 902, and the sacrificial filler layer 2004 are removed during formation of the replacement gates (see below).

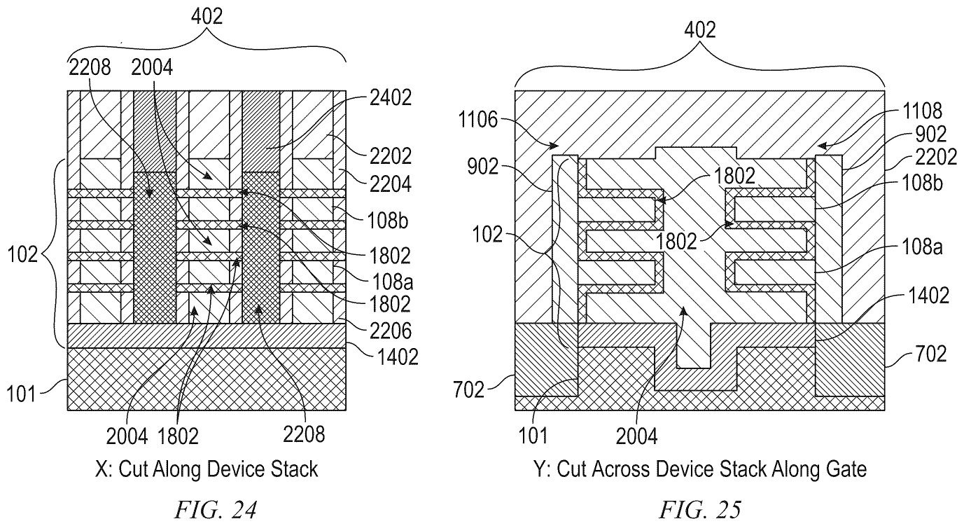

As shown in FIG. 24 (an X cross-sectional view) and FIG. 25 (a Y cross-sectional view), the sacrificial gates 2202 and gate spacers 2204 are buried in an interlayer dielectric 2402, which is then planarized thereby removing the gate hardmasks 2201. For clarity, the term ‘third’ may also be used herein when referring to interlayer dielectric 2402 in order to distinguish it from the ‘first’ interlayer dielectric 702 and the ‘second’ interlayer dielectric 1102. Interlayer dielectric 2402 will facilitate removal and replacement of the sacrificial gates 2202 with the replacement gates (see below).

As provided above, suitable interlayer dielectric 2402 materials include, but are not limited to, oxide low-κ materials such as SiOx and/or oxide ULK-ILD materials such as pSiCOH. A process such as CVD, ALD or PVD can be used to deposit the interlayer dielectric 2402, after which the interlayer dielectric 2402 can be planarized using a process such as chemical mechanical polishing. Interlayer dielectric 2402 will facilitate removal and replacement of the sacrificial gates 2202 with the replacement gates (see below).

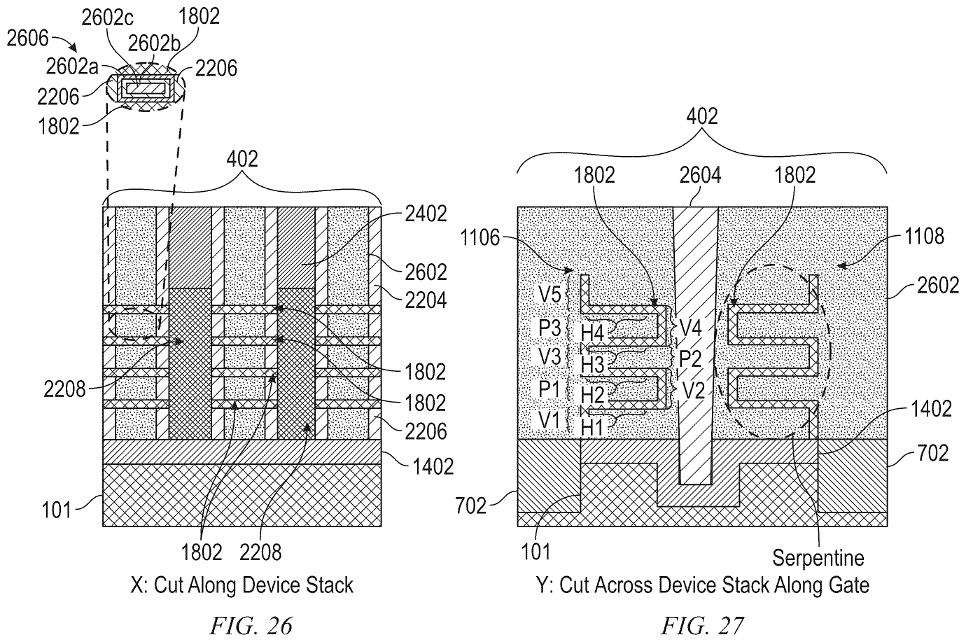

Finally, as shown in in FIG. 26 (an X cross-sectional view) and FIG. 27 (a Y cross-sectional view), the sacrificial gates 2202 are selectively removed, the third sacrificial nanosheets 108a,b, etc., the epitaxial sidewalls 902, and the sacrificial filler layer 2004 are then also removed, replacement gates 2602 are formed surrounding at least a portion of each of the channel layers 1802 in a gate-all-around configuration, and a gate cut 2604 is formed in the replacement gates 2602. As provided above, sacrificial gates 2202 can be formed from a material such as poly-silicon and/or amorphous silicon. In that case, a poly-silicon or amorphous silicon-selective etching process can be employed to remove the sacrificial gates 2202.

Removal of the sacrificial gates 2202 exposes the underlying layers and enables the selective removal of the third sacrificial nanosheets 108a,b, etc., the epitaxial sidewalls 902, and the sacrificial filler layer 2004. According to an exemplary embodiment, the third sacrificial nanosheets 108a,b, etc., the epitaxial sidewalls 902, and the sacrificial filler layer 2004 are all formed from SiGe, while channel layers 1802 are formed from (tensile stressed) Si. In that case, etchants such as wet hot SC1, vapor phase HCl, vapor phase CIF₃ and/or other reactive clean processes can be employed to remove the third sacrificial nanosheets 108a,b, etc., the epitaxial sidewalls 902, and the sacrificial filler layer 2004 selective to the channel layers 1802. Removal of the third sacrificial nanosheets 108a,b, etc., the epitaxial sidewalls 902, and the sacrificial filler layer 2004 releases and suspends the channel layers 1802. However, as described above, the ends of the channel layers 1802 are anchored by the source/drain regions 2208 which maintain the tensile strain in the channel layers 1802 even after they are released.

Replacement gates 2602 are then formed surrounding at least a portion of each of the channel layers 1802 in a gate-all-around configuration. The term ‘gates’ may also be used herein when referring to replacement gates 2602, and the skilled artisan will appreciate from the context whether reference is being made to the “dummy” gates or the “replacement” gates. Looking at magnified view 2606 in FIG. 26, according to an exemplary embodiment, formation of the replacement gates 2602 begins with the deposition of a (conformal) gate dielectric 2602a onto/surrounding each of the channel layers 1802. According to an exemplary embodiment, the gate dielectric 2602a is a high-κ material. The term “high-κ,” as used herein, refers to a material having a relative dielectric constant κ which is much higher than that of silicon dioxide (e.g., a dielectric constant κ=25 for hafnium oxide (HfO₂) rather than 4 for SiO₂). Suitable high-k gate dielectrics include, but are not limited to, hafnium oxide (HfO₂) and/or lanthanum oxide (La₂O₃). The term “high-κ” has a definite meaning to the skilled artisan in the context of high-κ metal gate (HKMG) stacks, and is not a mere relative term. A process such as CVD, ALD or PVD can be employed to deposit the gate dielectric 2602a. According to an exemplary embodiment, gate dielectric 2602a has a thickness of from about 1 nm to about 5 nm and ranges therebetween. A reliability anneal can be performed following deposition of the gate dielectric 2602a. In one exemplary embodiment, the reliability anneal is performed at a temperature of from about 500° C. to about 1200° C. and ranges therebetween, for a duration of from about 1 nanosecond to about 30 seconds and ranges therebetween. Preferably, the reliability anneal is performed in the presence of an inert gas such as, but not limited to, nitrogen.

At least one workfunction-setting metal 2602b is then deposited over the gate dielectric 2602a. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). A process such as CVD, ALD or PVD can be employed to deposit the workfunction-setting metal(s) 2602b, after which the metal overburden can be removed using a process such as chemical mechanical polishing.

Optionally, a (low-resistance) fill metal 2602c can be deposited over the workfunction-setting metal(s) 2602b so as to fill in any remaining spaces in the replacement gates 2602. Suitable low-resistance fill metals 2602c include, but are not limited to, W, cobalt (Co), ruthenium (Ru) and/or Al, which can be deposited using a process or combination of processes including, but not limited to, CVD, ALD, PVD, sputtering, plating, evaporation, ion beam deposition, electron beam deposition, laser assisted deposition, chemical solution deposition, etc.

To form the gate cut 2604, a gate cut opening is created in the replacement gates 2602 between adjacent device stacks 1106 and 1108. Standard lithography and etching techniques (see above) can be employed to pattern the gate cut opening in the replacement gates 2602. The gate cut opening is then filled with a gate cut dielectric material to form the gates cut 2604 which will serve to isolate the gates of different field-effect transistors. Thus, what is visible as the gate cut 2604 in the figures is the gate cut dielectric material. Suitable gate cut dielectric materials include, but are not limited to, SiN, SiOx, SiC and/or SiCO, which can be deposited into the gate cut opening using a process such as CVD, ALD or PVD. Following deposition, the excess gate cut dielectric material can be removed using a process such as chemical mechanical polishing.

As shown, for example, in FIG. 26 and FIG. 27, a plurality of field-effect transistors is now present on the substrate 101. Each of the field-effect transistors includes a channel layer 1802, a replacement gate 2602 (or simply a ‘gate’) surrounding the channel layer 1802 in a gate-all-around configuration, and source/drain regions 2208 on opposite ends of the channel layer 1802. Notably, with the present design, the channel layers 1802 have a unique configuration. Namely, each of the channel layers 1802 has both horizontal portions (see, e.g., portions H1, H2, H3 and H4 in FIG. 27) and vertical portions (see, e.g., portions V1, V2, V3, V4 and V5 in FIG. 27). The vertical portions connect adjacent horizontal portions of the channel layers 1802. For instance, vertical portion V2 connects horizontal portions H1 and H2, vertical portion V3 connects horizontal portions H2 and H3, vertical portion V4 connects horizontal portions H3 and H4, and so on.

In the exemplary embodiment depicted in FIG. 27, the vertical portions connect every adjacent pair of the horizontal portions from alternating sides which results in a serpentine configuration of the channel layers 1802. For instance, the adjacent pair of horizontal portions H1 and H2 are connected by vertical portion V2 on a first side (arbitrarily shown as the right side in FIG. 27) of channel layer 1802, the next adjacent pair of horizontal portions H2 and H3 are connected by vertical portion V3 on a second side (arbitrarily shown as the left side in FIG. 27), the next adjacent pair of horizontal portions H3 and H4 are connected by vertical portion V4 on the first side of channel layer 1802, and so on. This arrangement is what is referred to herein as a “serpentine configuration.” Further, this serpentine configuration is extended by vertical portions V1 and V5, and continues all the way down to the dielectric 1402 which separates the source/drain regions 2208 from the substrate 101.

As a result of this serpentine configuration of the channel layers 1802, multiple portions of the replacement gate 2602 will be present in between adjacent horizontal portions of the channel layer 1802. For instance, referring to FIG. 27, a portion P1 of the replacement gate 2602 is now present between the pair of adjacent horizontal portions H1 and H2 of the channel layer 1802, a portion P2 of the replacement gate 2602 is now present between the pair of adjacent horizontal portions H2 and H3 of the channel layer 1802, a portion P3 of the replacement gate 2602 is now present between the pair of adjacent horizontal portions H3 and H4 of the channel layer 1802, and so on.

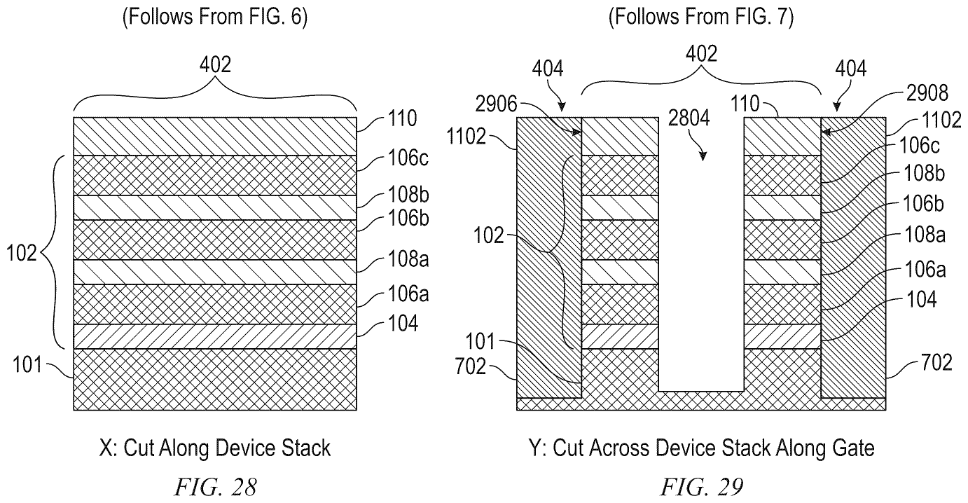

In the example just described, the epitaxial sidewalls 902 template growth of every other vertical portion, thereby enabling the present serpentine configuration of the channel layers 1802. However, as described above, formation of the epitaxial sidewalls 902 requires additional interlayer dielectric recess and epitaxial growth steps. In the following alternative embodiment, the epitaxial sidewalls 902 needed for a ‘fully-connected’ serpentine configuration of the channel layers 1802 are eliminated from the process flow in favor of a ‘partially-connected’ design whereby the vertical portions connect adjacent pairs of the horizontal portions to form sideways-facing U-shaped segments of the channel layers. This alternative embodiment is now described by way of reference to FIGS. 28-45.

The process begins in the same manner as with the previous example. Namely, as described in conjunction with the description of FIGS. 1-7 above, the nanosheet stack 102 is formed on the substrate 101, the nanosheet stack 102 having a first sacrificial nanosheet 104 blanket deposited on substrate 101, and alternating second and third sacrificial nanosheets 106a,b,c, etc. and 108a,b, etc. blanket deposited horizontally one on top of another on the first sacrificial nanosheet 104. As described in detail above, embodiments are contemplated herein where the first sacrificial nanosheet 104 is formed from high Ge content (i.e., SiGe having from about 45% Ge to about 70% Ge) such as SiGe55, the second sacrificial nanosheets 106a,b,c, etc. are formed from Si, and the third sacrificial nanosheets 108a,b, etc. are formed from a low Ge content SiGe (i.e., SiGe having from about 15% Ge to about 35% Ge) such as SiGe25. The hardmask 110 is then used to patten the nanosheet stack 102 in the active area 402 of the semiconductor device, forming the trenches 404 along opposite sides of the nanosheet stack 102 and substrate 101. The trenches 404 are then filled with the interlayer dielectric 702. Thus, FIG. 28 and FIG. 29 follow from what is shown in FIG. 6 and FIG. 7, respectively.

In this example, however, an early recess of the interlayer dielectric 702 is not performed. Namely, as shown in FIG. 28 (an X cross-sectional view) and FIG. 29 (a Y cross-sectional view), the hardmask 110 is next used to pattern a trench 2804 in the nanosheet stack 102 forming at least a first device stack 2906 and a second device stack 2908.

As described above, standard lithography and etching techniques can be employed to pattern the hardmask 110 with the footprint and location of the trench 2804. A directional (i.e., anisotropic) etching process such as reactive ion etching can then be employed to transfer the pattern to the nanosheet stack 102 forming the trench 2804. As shown particularly in FIG. 29, the etch of trench 2804 can extend partway into the substrate 101. The depth of this ‘overetch’ into the substrate 101 depends on the level of control over the endpoint of the etching process. The patterning of trench 2804 in nanosheet stack 102 results in the formation of the at least two distinct first/second device stacks 2906 and 2908 (which are representative of the exemplary device stacks shown in the top-down view of FIG. 1).

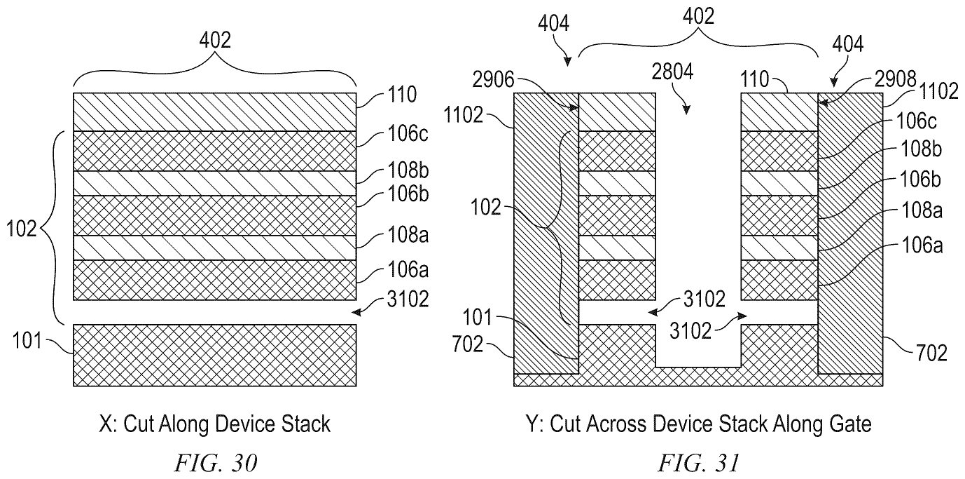

As shown in in FIG. 30 (an X cross-sectional view) and FIG. 31 (a Y cross-sectional view), the first sacrificial nanosheet 104 is selectively removed from the nanosheet stack 102 via the trench 2804. As provided above, the first sacrificial nanosheet 104 can be formed from SiGe having a high Ge content (i.e., SiGe having from about 45% Ge to about 70% Ge) such as SiGe55, while the third sacrificial nanosheets 108a,b, etc. can be formed from a low Ge content SiGe (i.e., SiGe having from about 15% Ge to about 35% Ge) such as SiGe25. In that case, an etchant such as dry HCl can be employed to remove the first sacrificial nanosheet 104 (having a high Ge content) selective to the third sacrificial nanosheets 108a,b, etc. (having a low Ge content), and selective to the second sacrificial nanosheets 106a,b,c, etc. (Si). Selective removal of the first sacrificial nanosheet 104 forms a cavity 3102 in the nanosheet stack 102.

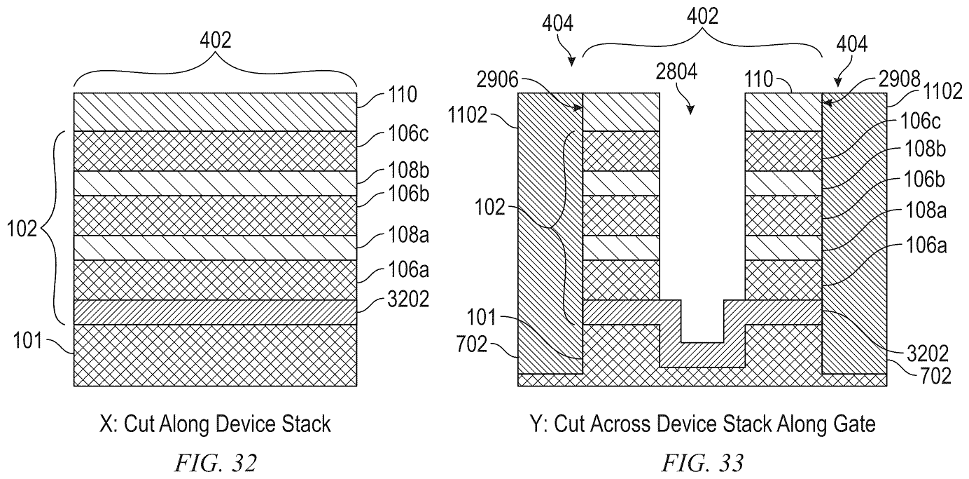

As shown in in FIG. 32 (an X cross-sectional view) and FIG. 33 (a Y cross-sectional view), a dielectric material is deposited into the trench 2804 and cavity 3102, and then chamfered to form a dielectric 3202 that separates/isolates the remaining nanosheet stack (i.e., the second and third sacrificial nanosheets 106a,b,c, etc., and 108a,b, etc.) from the substrate 101. This dielectric 3202 will advantageously serve to prevent source-to-drain leakage via the substrate 101.

Suitable materials for dielectric 3202 include, but are not limited to nitride dielectric materials such as SiN, SiOₓN_{y} and/or SiOCN. A process such as CVD, ALD or PVD can be used to deposit the dielectric 3202, after which the dielectric 3202 can be planarized using a process such as chemical mechanical polishing. Chamfering is then used to recess the dielectric 3202 such that dielectric 3202 remains only at the bottom of the trench 2804 and fully filling the cavity 3102, as shown in FIGS. 32 and 33.

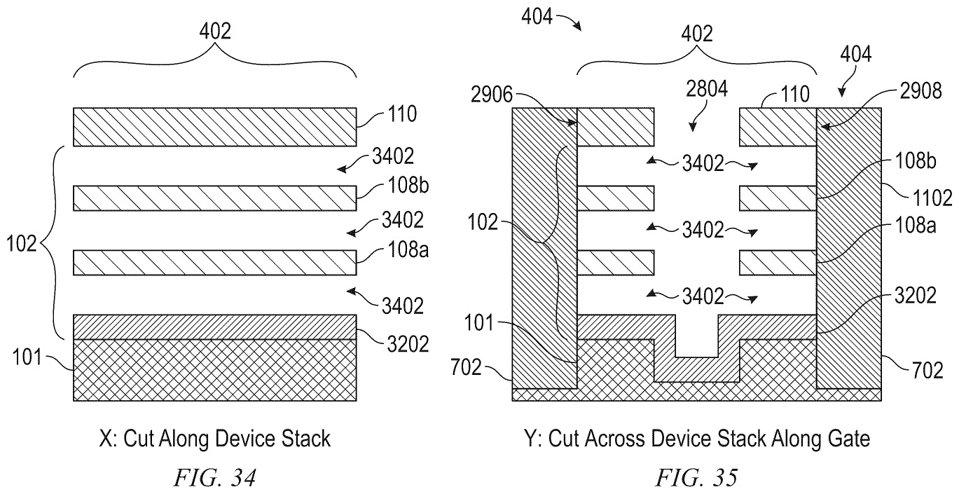

As shown in in FIG. 34 (an X cross-sectional view) and FIG. 35 (a Y cross-sectional view), the second sacrificial nanosheets 106a,b,c, etc. are then selectively removed from the nanosheet stack 102 via the trench 2804. In the same manner as above, removal of the second sacrificial nanosheets 106a,b,c, etc. will enable growth of the present tensile-strained Si channel layers over the now exposed surfaces of the third sacrificial nanosheets 108a,b, etc.

As provided above, the second sacrificial nanosheets 106a,b,c, etc. can be formed from Si, while the third sacrificial nanosheets 108a,b, etc. can be formed from SiGe. In that case, an etchant such as NH₄OH or TMAH can be employed to remove the second sacrificial nanosheets 106a,b,c, etc. selective to the third sacrificial nanosheets 108a,b, etc. Selective removal of the second sacrificial nanosheets 106a,b,c, etc. forms openings 3402 in the nanosheet stack 102 between the third sacrificial nanosheets 108a,b, etc.

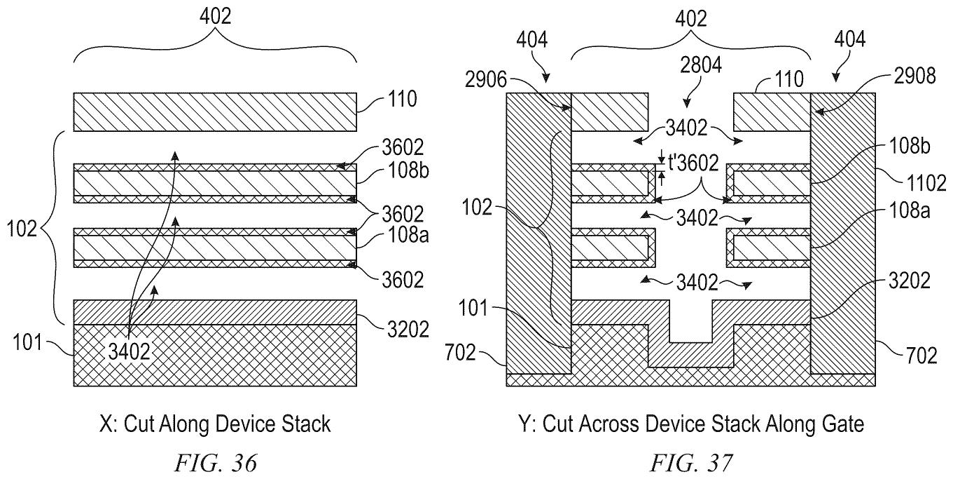

As shown in in FIG. 36 (an X cross-sectional view) and FIG. 37 (a Y cross-sectional view), channel layers 3602 are then deposited (i.e., epitaxially grown) in the openings 3402 on the exposed surfaces of the third sacrificial nanosheets 108a,b, etc. As above, the channel layers 3602 are preferably formed from a material having a larger elastic constant than the material on which the channel layers 3602 are epitaxially grown, namely the third sacrificial nanosheets 108a,b, etc. Doing so can serve to impart tensile strain on the channel layers 3602 which, as highlighted above, advantageously improves electron mobility in NFETs.

For instance, according to an exemplary embodiment, the third sacrificial nanosheets 108a,b, etc. are formed from SiGe, and the channel layers 3602 are formed from Si. As described in detail above, SiGe has a larger lattice constant than Si. Thus, when Si is grown epitaxially in this manner, the exposed SiGe surfaces of the third sacrificial nanosheets 108a,b, etc. act as a template for how the Si atoms are arranged. Since, SiGe has a larger lattice constant from that of Si, in order for the Si to match that template it has to be strained somehow, meaning the Si has to assume a different lattice parameter than it would have if it was deposited directly on another Si substrate. This causes the Si to stretch resulting in tensile stressed (Si) channel layers 3602.

As also described in detail above, the amount of shared strain is based on the relative thickness of the layers. According to an exemplary embodiment, the channel layers 3602 have a thickness t′ of from about 4 nm to about 10 nm, which is thinner than the third sacrificial nanosheets 108a,b, etc. on which the channel layers 3602 are grown. For instance, as provided above, the third sacrificial nanosheets 108a,b, etc. each have a thickness of from about 15 nm to about 25 nm. Accordingly, the relatively thinner Si channel layers 3602 will be fully strained, without having much, if any, effect on the SiGe third sacrificial nanosheets 108a,b, etc.

Additionally, when at the present thickness t′ (i.e., of from about 4 nm to about 10 nm), the channel layers 3602 can sustain a length of less than or equal to about 100 nm and greater than or equal to about 300 MPa of stress (e.g., from about 300 MPa to about 1 GPa of stress) without the risk of buckling, which should advantageously be avoided when the channel layers 3602 are released for the present gate-all-around process.

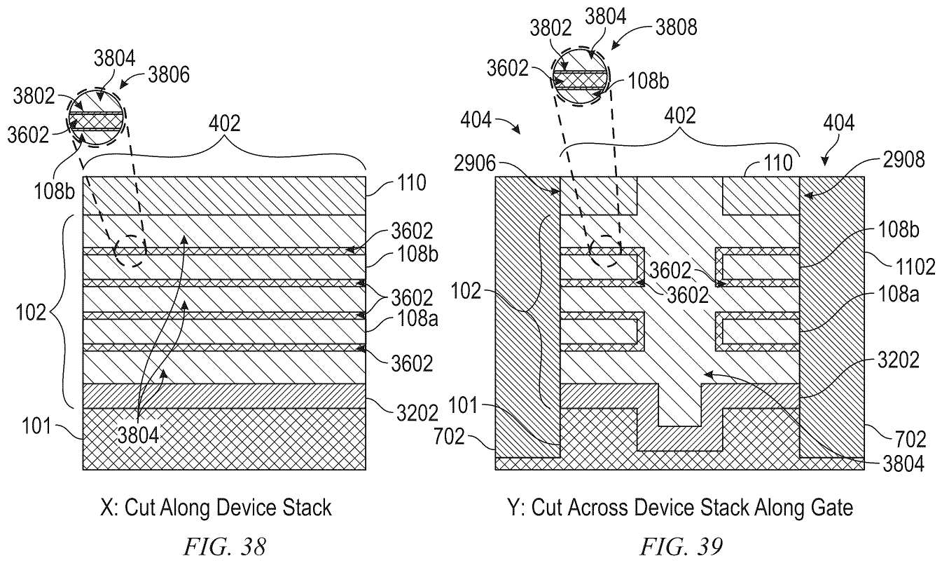

As shown in in FIG. 38 (an X cross-sectional view) and FIG. 39 (a Y cross-sectional view), a sacrificial filler layer 3804 is deposited into, and filling, the trench 2804 and openings 3402 over the channel layers 3602. In the instant exemplary embodiment, the third sacrificial nanosheets 108a,b, etc. are formed from SiGe, and the channel layers 3602 are formed from Si. In that case, the sacrificial filler layer 3804 is formed from SiGe, which can be deposited using a process such as thermal CVD or plasma-enhanced CVD. Doing so will later enable the concurrent removal of the third sacrificial nanosheets 108a,b, etc. and the sacrificial filler layer 3804 during replacement gate formation since they are all formed from the same material, in this case SiGe. According to one exemplary, non-limiting embodiment, sacrificial filler layer 3804 is formed from amorphous SiGe. As above, use of an amorphous material in this step will help to prevent the sacrificial filler layer 3804 from affecting the tensile strain already imparted on the channel layers 3602 by the third sacrificial nanosheets 108a,b, etc.

As shown in magnified view 3806 (of FIG. 38) and magnified view 3808 (of FIG. 39), an optional oxide layer 3802 (e.g., SiO₂) may first be deposited on the exposed surfaces of the channel layers 3602 prior to deposition of the sacrificial filler layer 3804. By way of example only, the oxide layer 3802 may be formed on the channel layers 3602 using a process such as thermal oxidation, to a thickness of from about 0.5 nm to about 1 nm. Use of the (optional) oxide layer 3802 will help avoid growth of single-crystal SiGe, in favor of the above-described amorphous SiGe. As noted above, native oxide on the surfaces of the channel layers 3602 may be sufficient to prevent growth of crystalline SiGe without the need for the intentional formation of SiO₂. As such, oxide layer 3802 is optional.

As above, the present exemplary process flow employs a gate-last process whereby sacrificial gates are used as a placeholder for positioning device components such as source/drain regions. Later on, the sacrificial gates are removed and replaced with the final or “replacement” gates of the device.

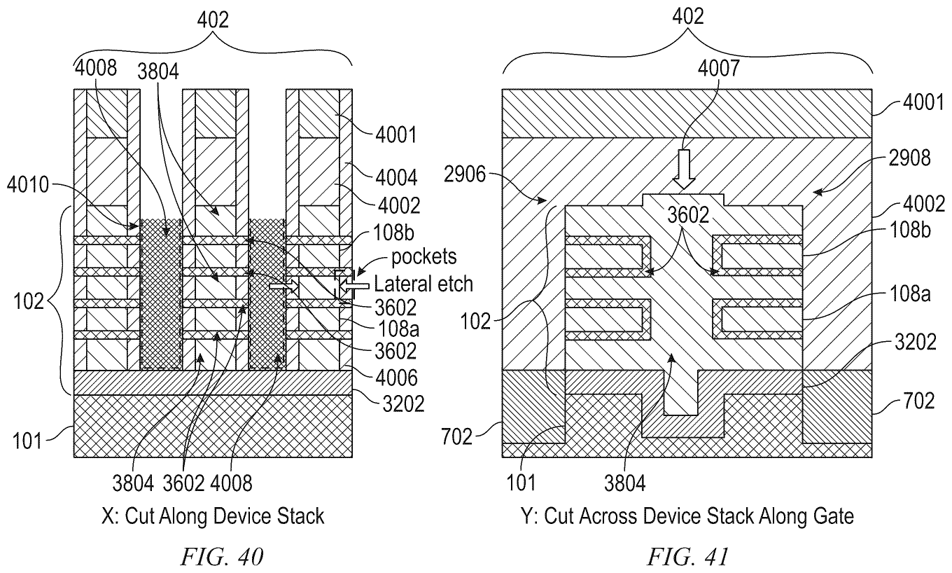

Accordingly, as shown in in FIG. 40 (an X cross-sectional view) and FIG. 41 (a Y cross-sectional view), the sacrificial filler layer 3804 is recessed, the interlayer dielectric 702 is recessed, the hardmask 110 is removed, sacrificial gates 4002 are formed over the nanosheet stack 102, gate spacers 4004 are formed alongside the sacrificial gates 4002 and the sacrificial filler layer 3804, inner spacers 4006 are formed alongside the third sacrificial nanosheets 108a,b, etc. and sacrificial filler layer 3804, and source/drain regions 4008 are formed on opposite ends of the channel layers 3602. The source/drain regions 4008 are offset from the sacrificial filler layer 3804 and the third sacrificial nanosheets 108a,b, etc. by the gate spacers 4004 and the inner spacers 4006, respectively.

Recess of the sacrificial filler layer 3804 is represented schematically by arrow 4007 in FIG. 41. As provided above, the sacrificial filler layer 3804 can be formed from SiGe, which can be selectively patterned using etchants such as wet hot SC1, vapor phase HCl, vapor phase CIF₃ and other RCPs. The interlayer dielectric 702 can be recessed using a dry or wet etching process. As shown particularly in FIG. 41, embodiments are contemplated herein where the interlayer dielectric 702 is recessed down to, and coplanar with, the dielectric 3202. As such, the nanosheet stack 102 above the dielectric 3202 is fully exposed. What remains of the hardmask 110 can then be removed using a nitride- or oxide-selective etch, as the case may be (see above).

To form the sacrificial gates 4002, a sacrificial gate material is first blanket deposited over the nanosheet stack 102. As provided above, suitable sacrificial gate materials include, but are not limited to, poly-silicon and/or amorphous silicon. A process such as CVD, ALD or PVD can be used to deposit the sacrificial gate material, after which the sacrificial gate material can be planarized using a process such as chemical mechanical polishing. Standard lithography and etching techniques (see above) are then used to pattern gate hardmasks 4001 on the sacrificial gate material marking the footprint and location of the sacrificial gates 4002. A directional (i.e., anisotropic) etching process such as reactive ion etching can be employed to transfer the pattern from the gate hardmasks 4001 to the sacrificial gate material, forming the sacrificial gates 4002 over the nanosheet stack 102 (which are representative of the exemplary gates shown in the top-down view of FIG. 1).

To form the gate spacers 4004, a dielectric spacer material is first deposited over the nanosheet stack 102, followed by a directional (anisotropic) etching process such as reactive ion etching to pattern the dielectric spacer material into the gate spacers 4004 alongside the sacrificial gates 4002 and the sacrificial filler layer 3804. As provided above, suitable dielectric spacer materials include, but are not limited to, SiOx, SiC, SiCO, SiN, SiBCN and/or SiOCN, which can be deposited using a process such as CVD, ALD or PVD.

As shown particularly in FIG. 40, the gate hardmasks 4001/sacrificial gates 4002 and gate spacers 4004 are then used as a mask to pattern trenches 4010 in the nanosheet stack 102, the outlines of which are depicted with dashed lines. A directional (anisotropic) etching process such as reactive ion etching can be employed to form the trenches 4010.

To form the inner spacers 4006, a selective lateral etch is performed to first recess the third sacrificial nanosheets 108a,b, etc. and the sacrificial filler layer 3804 exposed along the sidewalls of the trenches 4010. This recess etch forms pockets along the sidewalls of the trenches 4010 that are then filled with a dielectric spacer material to form the inner spacers 4006 within the pockets. The inner spacers 4006 will serve to offset the replacement gates from the source/drain regions (see below). As provided above, the third sacrificial nanosheets 108a,b, etc. and the sacrificial filler layer 3804 can be formed from SiGe. In that case, a SiGe-selective non-directional (isotropic) etching process can be used for the recess etch. As provided above, suitable dielectric spacer materials for inner spacers 4006 include, but are not limited to, SiN, SiOx, SiC and/or SiCO. A process such as CVD, ALD or PVD can be employed to deposit the dielectric spacer material into the pockets, after which excess spacer material can be removed from the trenches 4010 using an isotropic etching process such as reactive ion etching.

Source/drain regions 4008 are then formed on opposite ends of the channel layers 3602. As provided above, a goal of the present techniques is to fabricate tensile stressed stacked nanosheet NFET devices. Thus, according to an exemplary embodiment, the source/drain regions 4008 are formed from an n-type in-situ doped (i.e., during growth) or ex-situ doped (e.g., via ion implantation) epitaxial material such as epitaxial Si, epitaxial SiGe, etc. Suitable n-type dopants include, but are not limited to, phosphorous (P) and/or arsenic (As).

Notably, as shown for example in FIG. 40, the source/drain regions 4008 now anchor the ends of the channel layers 3602. In this manner, the tensile strain present in the channel layers 3602 can be maintained (i.e., anchored) even after the third sacrificial nanosheets 108a,b, etc. and the sacrificial filler layer 3804 are removed during formation of the replacement gates.

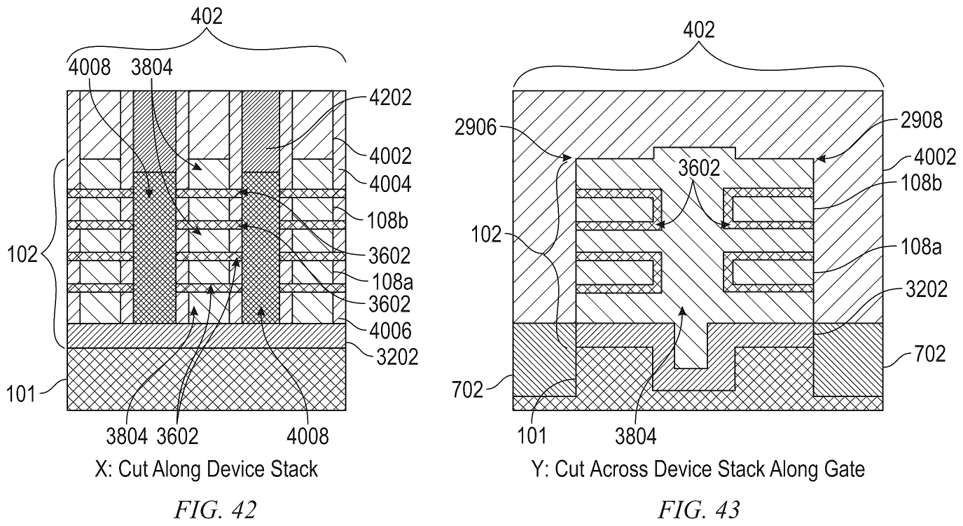

As shown in FIG. 42 (an X cross-sectional view) and FIG. 43 (a Y cross-sectional view), the sacrificial gates 4002 and gate spacers 4004 are buried in an interlayer dielectric 4202, which is then planarized thereby removing the gate hardmasks 4001. For clarity, the terms ‘first’ and ‘second’ may also be used herein when referring to interlayer dielectric 702 and interlayer dielectric 4202, respectively.

As provided above, suitable interlayer dielectric 4202 materials include, but are not limited to, oxide low-κ materials such as SiOx and/or oxide ULK-ILD materials such as pSiCOH. A process such as CVD, ALD or PVD can be used to deposit the interlayer dielectric 4202, after which the interlayer dielectric 4202 can be planarized using a process such as chemical mechanical polishing. Interlayer dielectric 4202 will facilitate removal and replacement of the sacrificial gates 4002 with the replacement gates (see below).

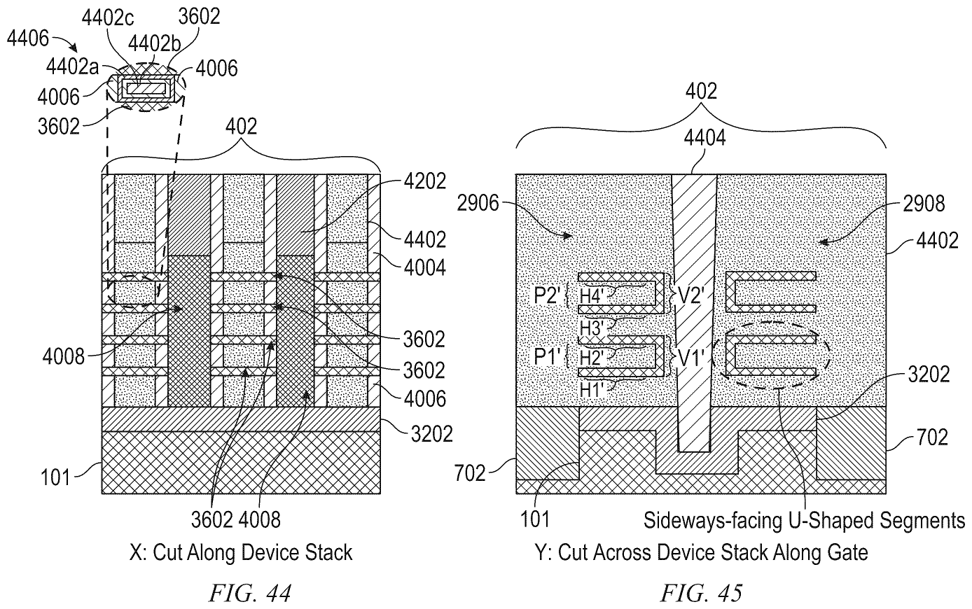

Finally, as shown in in FIG. 44 (an X cross-sectional view) and FIG. 45 (a Y cross-sectional view), the sacrificial gates 4002 are selectively removed, the third sacrificial nanosheets 108a,b, etc., and the sacrificial filler layer 3804 are then also removed, replacement gates 4402 are formed surrounding at least a portion of each of the channel layers 3602 in a gate-all-around configuration, and a gate cut 4404 is formed in the replacement gates 4402. As provided above, sacrificial gates 4002 can be formed from a material such as poly-silicon and/or amorphous silicon. In that case, a poly-silicon or amorphous silicon-selective etching process can be employed to remove the sacrificial gates 4002.

Removal of the sacrificial gates 4002 exposes the underlying layers and enables the selective removal of the third sacrificial nanosheets 108a,b, etc. and the sacrificial filler layer 3804. According to an exemplary embodiment, the third sacrificial nanosheets 108a,b, etc. and the sacrificial filler layer 3804 are all formed from SiGe, while channel layers 3602 are formed from (tensile stressed) Si. In that case, etchants such as wet hot SC1, vapor phase HCl, vapor phase CIF₃ and/or other reactive clean processes can be employed to remove the third sacrificial nanosheets 108a,b, etc. and the sacrificial filler layer 3804 selective to the channel layers 3602. Removal of the third sacrificial nanosheets 108a,b, etc. and the sacrificial filler layer 3804 releases and suspends the channel layers 3602. However, as described above, the ends of the channel layers 3602 are anchored by the source/drain regions 4008 which maintain the tensile strain in the channel layers 3602 even after they are released.

Replacement gates 4402 are then formed surrounding at least a portion of each of the channel layers 3602 in a gate-all-around configuration. As above, the term ‘gates’ may also be used herein when referring to replacement gates 4402. Looking at magnified view 4406 in FIG. 44, according to an exemplary embodiment, formation of the replacement gates 4402 begins with the deposition of a (conformal) gate dielectric 4402a onto/surrounding each of the channel layers 3602. According to an exemplary embodiment, the gate dielectric 4402a is a high-k material. As provided above, suitable high-κ gate dielectrics include, but are not limited to, HfO₂ and/or La₂O₃. A process such as CVD, ALD or PVD can be employed to deposit the gate dielectric 4402a. According to an exemplary embodiment, gate dielectric 4402a has a thickness of from about 1 nm to about 5 nm and ranges therebetween. A reliability anneal can be performed following deposition of the gate dielectric 4402a. In one exemplary embodiment, the reliability anneal is performed at a temperature of from about 500° C. to about 1200° C. and ranges therebetween, for a duration of from about 1 nanosecond to about 30 seconds and ranges therebetween. Preferably, the reliability anneal is performed in the presence of an inert gas such as, but not limited to, nitrogen.

At least one workfunction-setting metal 4402b is then deposited over the gate dielectric 4402a. As provided above, suitable n-type workfunction-setting metals include, but are not limited to, TiN, TaN and/or Al-containing alloys such as TiAl, TiAlN, TiAlC, TaAl, TaAlN, and/or TaAlC. A process such as CVD, ALD or PVD can be employed to deposit the workfunction-setting metal(s) 4402b, after which the metal overburden can be removed using a process such as chemical mechanical polishing.

Optionally, a (low-resistance) fill metal 4402c can be deposited over the workfunction-setting metal(s) 4402b so as to fill in any remaining spaces in the replacement gates 4402. Suitable low-resistance fill metals 4402c include, but are not limited to, W, Co, Ru and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

To form the gate cut 4404, a gate cut opening is created in the replacement gates 4402 between adjacent device stacks 2906 and 2908. Standard lithography and etching techniques (see above) can be employed to pattern the gate cut opening in the replacement gates 4402. The gate cut opening is then filled with a gate cut dielectric material to form the gate cut 4404 which will serve to isolate the gates of different field-effect transistors. Thus, what is visible as the gate cut 4404 in the figures is the gate cut dielectric material. As provided above, suitable gate cut dielectric materials include, but are not limited to, SiN, SiOx, SiC and/or SiCO, which can be deposited into the gate cut opening using a process such as CVD, ALD or PVD. Following deposition, the excess gate cut dielectric material can be removed using a process such as chemical mechanical polishing.

As shown, for example, in FIG. 44 and FIG. 45, a plurality of field-effect transistors is now present on the substrate 101. Each of the field-effect transistors includes a channel layer 3602, a replacement gate 4402 (or simply a ‘gate’) surrounding the channel layer 3602 in a gate-all-around configuration, and source/drain regions 4008 on opposite ends of the channel layer 3602. Notably, with the present design, the channel layers 3602 have a unique configuration. As in the previous example, each of the channel layers 3602 has both horizontal portions (see, e.g., portions H1′, H2′, H3′ and H4′ in FIG. 45) and vertical portions (see, e.g., portions V1′ and V2′ in FIG. 45). The vertical portions connect adjacent horizontal portions of the channel layers 3602. For instance, vertical portion V1′ connects horizontal portions H1′ and H2′, vertical portion V2′ connects horizontal portions H3′ and H4′, and so on.

However, as compared to the example above, the vertical portions connect every other pair of the horizontal portions from the same side which results in the channel layers 1802 having sideways-facing U-shaped segments. For instance, the pair of horizontal portions H1′ and H2′ are connected by vertical portion V1′ on a side of channel layer 3602 facing the gate cut 4404, the next pair of horizontal portions H3′ and H4′ are connected by vertical portion V2′ on the same side of channel layer 3602 facing the gate cut 4404, and so on. This arrangement forms what is referred to herein as “sideways-facing U-shaped segments” of the channel layer 3602. As compared to the above fully-connected, serpentine configuration, the sideways-facing U-shaped segments are not connected (i.e., unconnected) to one another. Thus, the horizontal and vertical portions of the channel layer 3602 in the sideways-facing U-shaped segments are considered to be partially-connected.

As a result of the sideways-facing U-shaped segments of the channel layers 3602, multiple portions of the replacement gate 4402 will be present in between adjacent horizontal portions of the channel layer 3602. For instance, referring to FIG. 45, a portion P1′ of the replacement gate 4402 is now present between the pair of adjacent horizontal portions H1′ and H2′ of the channel layer 3602, a portion P2′ of the replacement gate 4402 is now present between the pair of adjacent horizontal portions H3′ and H4′ of the channel layer 3602, and so on.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary field effect transistor (FET) device includes: a channel layer 1802/3602 disposed on a substrate 101, where the channel layer 1802/3602 has both horizontal and vertical portions, and where the vertical portions of the channel layer 1802/3602 connect adjacent ones of the horizontal portions; a gate 2602/4402 surrounding the channel layer 1802/3602; and source/drain regions 2208/4008 on opposite ends of the channel layer 1802/3602.

In accordance with another aspect of the invention, another exemplary FET device includes: a channel layer 1802/3602 of tensile strained Si disposed on a substrate 101, where the channel layer 1802/3602 has both horizontal and vertical portions, and where the vertical portions of the channel layer 1802/3602 connect adjacent ones of the horizontal portions; a gate 2602/4402 surrounding the channel layer 1802/3602 in a gate-all-around configuration, where portions of the gate 2602/4402 are present between the horizontal portions of the channel layer 1802/3602; and source/drain regions 2208/4008 on opposite ends of the channel layer 1802/3602.

In accordance with yet another aspect of the invention, an exemplary method of fabricating a FET device includes: forming a nanosheet stack 102 on a substrate 101, the nanosheet stack 102 having a first sacrificial nanosheet 104 disposed on the substrate 101, and alternating second and third sacrificial nanosheets 106a,b,c, etc. and 108a,b, etc. disposed on the first sacrificial nanosheet 104; selectively removing the second sacrificial nanosheets 106a,b,c, etc. from the nanosheet stack 102; depositing a channel layer 1802/3602 on the third sacrificial nanosheets 108a,b, etc., where the channel layer 1802/3602 has both horizontal and vertical portions, and where the vertical portions of the channel layer 1802/3602 connect adjacent ones of the horizontal portions; depositing a sacrificial filler layer 2004/3804 over the channel layer 1802/3602; forming source/drain regions 2208/4008 on opposite ends of the channel layer 1802/3602; selectively removing the third sacrificial nanosheets 108a,b, etc. and the sacrificial filler layer 2004/3804; and forming a gate 2602/4402 that surrounds the channel layer 1802/3602 in a gate-all-around configuration.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed tensile stressed NFET nanosheets scheme.

An integrated circuit in accordance with aspects of the present inventions can be employed in essentially any application and/or electronic system where one or more aspects of the disclosed tensile stressed NFET nanosheets scheme would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A field effect transistor (FET) device, comprising:
a channel layer disposed on a substrate, wherein the channel layer comprises both horizontal and vertical portions, and wherein the vertical portions of the channel layer connect adjacent ones of the horizontal portions;
a gate surrounding the channel layer; and
source/drain regions on opposite ends of the channel layer.

2. The FET device of claim 1, wherein the channel layer comprises silicon (Si).

3. The FET device of claim 1, wherein the channel layer is strained with tensile strain.

4. The FET device of claim 1, wherein the vertical portions of the channel layer connect every adjacent pair of the horizontal portions of the channel layer from alternating sides, thereby resulting in a serpentine configuration of the channel layer.

5. The FET device of claim 4, further comprising:
a dielectric separating the source/drain regions from the substrate.

6. The FET device of claim 5, wherein the serpentine configuration of the channel layer extends down to the dielectric.

7. The FET device of claim 1, wherein the vertical portions of the channel layer connect every other pair of the horizontal portions of the channel layer from a same side, thereby resulting in the channel layer comprising sideways-facing U-shaped segments.

8. The FET device of claim 1, wherein the sideways-facing U-shaped segments are unconnected to one another.

9. The FET device of claim 1, wherein portions of the gate are present between the horizontal portions of the channel layer.

10. The FET device of claim 1, wherein the channel layer has a thickness of from about 4 nanometers to about 10 nanometers.

11. A field effect transistor (FET) device, comprising:
a channel layer comprising tensile strained silicon (Si) disposed on a substrate, wherein the channel layer comprises both horizontal and vertical portions, and wherein the vertical portions of the channel layer connect adjacent ones of the horizontal portions;
a gate surrounding the channel layer in a gate-all-around configuration, wherein portions of the gate are present between the horizontal portions of the channel layer; and
source/drain regions on opposite ends of the channel layer.

12. The FET device of claim 11, wherein the vertical portions of the channel layer connect every adjacent pair of the horizontal portions of the channel layer from alternating sides, thereby resulting in a serpentine configuration of the channel layer.

13. The FET device of claim 11, wherein the vertical portions of the channel layer connect every other pair of the horizontal portions of the channel layer from a same side, thereby resulting in the channel layer comprising sideways-facing U-shaped segments.

14. A method of fabricating a field effect transistor (FET) device, the method comprising:
forming a nanosheet stack on a substrate, the nanosheet stack comprising a first sacrificial nanosheet disposed on the substrate, and alternating second and third sacrificial nanosheets disposed on the first sacrificial nanosheet;
selectively removing the second sacrificial nanosheets from the nanosheet stack;
depositing a channel layer on the third sacrificial nanosheets, wherein the channel layer comprises both horizontal and vertical portions, and wherein the vertical portions of the channel layer connect adjacent ones of the horizontal portions;
depositing a sacrificial filler layer over the channel layer;
forming source/drain regions on opposite ends of the channel layer;
selectively removing the third sacrificial nanosheets and the sacrificial filler layer; and
forming a gate that surrounds the channel layer in a gate-all-around configuration.

15. The method of claim 14, wherein the first sacrificial nanosheet, the third sacrificial nanosheets, and the sacrificial filler layer each comprises silicon germanium (SiGe), wherein the second sacrificial nanosheets comprise silicon (Si), and wherein the channel layer comprises Si.

16. The method of claim 14, wherein the channel layer comprises tensile strain, and wherein the source/drain regions anchor the tensile strain in the channel layer prior to forming the gate.

17. The method of claim 14, further comprising:
forming epitaxial sidewalls alongside the nanosheet stack; and
depositing the channel layer on the third sacrificial nanosheets and on the epitaxial sidewalls.

18. The method of claim 17, wherein the vertical portions of the channel layer connect every adjacent pair of the horizontal portions of the channel layer from alternating sides, thereby resulting in a serpentine configuration of the channel layer.

19. The method of claim 18, further comprising:
selectively removing the first sacrificial nanosheet to form a cavity in the nanosheet stack; and
depositing a dielectric into the cavity, wherein the dielectric separates the source/drain regions from the substrate, and wherein the serpentine configuration is continuous down to the dielectric.

20. The method of claim 14, wherein the vertical portions of the channel layer connect every other pair of the horizontal portions of the channel layer from a same side, thereby resulting in the channel layer comprising sideways-facing U-shaped segments.
